(19) United States
(12) Patent Application Publication
(10) Pub. No.: US 2024/0414965 A1
(43) Pub. Date: Dec. 12, 2024

(54) DISPLAY MODULES AND MANUFACTURING METHODS THEREOF

(71) Applicants: Yunnan Invensight Optoelectronics Technology Co., Ltd., Kunming, Yunnan (CN); BOE Technology Group Co., Ltd., Beijing (CN)

(72) Inventors: Dongdong SU, Beijing (CN); Hongtao YU, Beijing (CN); Yunhao ZHANG, Beijing (CN); Zongshun YANG, Beijing, (CN); Zhongxiang YU, Beijing (CN); Chao YANG, Beijing (CN); Fushuang ZHANG, Beijing (CN); Renqi XIE, Beijing (CN); Zhoujun SHAO, Beijing (CN); Weiliang BU, Beijing (CN); Kuanta HUANG, Beijing (CN)

(21) Appl. No.: 18/696,969

(22) PCT Filed: Jul. 31, 2023
(86) PCT No.: PCT/CN2023/110333

§ 371 Date: Mar. 28, 2024

(30) Foreign Application Priority Data
Aug. 10, 2022 (CN) 202210957734.3

(51) Int. Cl. H10K 59/131; H10K 59/12; H10K 59/122

(52) U.S. Cl. CPC H10K 59/131; H10K 59/1201; H10K 59/122

(57) ABSTRACT

The present disclosure relates to a display module and a manufacturing method thereof. The display module includes a display region and a non-display region located on the periphery of the display region. The display module includes an array substrate, a first inorganic layer, a second inorganic layer, a first mounting groove, and an electrode wire. The first inorganic layer is provided on the array substrate. The first inorganic layer includes a first inorganic part located in the non-display region. The second inorganic layer is provided on a side of the first inorganic layer far from the array substrate. The second inorganic layer includes a second inorganic part located on the first inorganic part. The first mounting groove is located in the non-display region and surrounds a portion of the display region, and the first mounting groove penetrates through the first inorganic part and the second inorganic part.

### TECHNICAL FIELD

The present disclosure belongs to the field of display technology, in particular to display modules and manufacturing methods thereof.

### BACKGROUND

With the development of display panel technology, organic-light-emitting-diode (OLED) display devices have advantages of all-solid-state structure, high brightness, full view angle, fast response speed, and support for flexible displays, and become highly competitive and promising next-generation display structures. Micro-OLED display products, as a commonly used organic-light-emitting-diode display device, are widely used. As shown in FIG. 1, in the relevant technology for manufacturing Micro-OLED display products, after forming an anode (not shown) on an array substrate 10′, there is a lateral height coverage (LHC) process to set an inorganic layer (such as a silicon oxide layer) between adjacent anodes, which can reduce the step height between the surface of an anode and the space region of adjacent anodes. In the LHC process, to ensure the height of the surface of anode metal and the height of the inorganic layer in the space region between adjacent anodes to be the same, an inorganic material layer is provided on the array substrate 10′ with an anode, and the inorganic material layer is etched to reduce the thickness to be relatively flush with the surface of the anode. The inorganic material layer provided in the LHC process further covers the margin region of the array substrate (which can be understood as a non-display region). However, the etching of the inorganic material layer is mainly based on the specific structure of the display region, which will result in a residual inorganic material layer 31′ remaining on the non-display layer. When a pixel defining layer is provided subsequently, the pixel defining layer is stacked above the inorganic material layer 31′ and extends to the inorganic layer 40′ in the non-display region, such that when a mounting groove 340′ for a cathode area is formed subsequently, the depth of the mounting groove 340′ is larger, and the step coverage ability of the cathode area material 50′ is not good, which is easy to cause breakage of the cathode area (such as fracture 501′) above the opening of the mounting groove 340 when the cathode area is formed.

### SUMMARY

According to the first aspect of the embodiments of the present disclosure, a display module including a display region and a non-display region at a periphery of the display region is provided, where the display module includes:
an array substrate;
a first inorganic layer on the array substrate, where the first inorganic layer includes a first inorganic part in the non-display region;
a second inorganic layer on a side of the first inorganic layer far from the array substrate, where the second inorganic layer includes a second inorganic part on the first inorganic part;
a first mounting groove in the non-display region, surrounding a portion of the display region, and penetrating through the first inorganic part and the second inorganic part, where the first mounting groove is in an open shape, and in a direction from the array substrate towards the second inorganic layer, a groove wall of the first mounting groove is inclined or stepped; and
an electrode wire layer at least partially in the first mounting groove.

In some embodiments, the groove wall of the first mounting groove is inclined, and a slope angle of the groove wall of the first mounting groove is 20° to 60°.

In some embodiments, the groove wall of the first mounting groove is stepped, and the groove wall of the first mounting groove includes a first groove wall close to the array substrate, a second groove wall far from the array substrate, and a third groove wall connected between the first groove wall and the second groove wall, where a step is formed by the third groove wall.

In some embodiments, the display module includes: first electrodes in the display region on the array substrate and arranged in an array, where the first inorganic layer further includes a third inorganic part between adjacent two of the first electrodes in the display region, and the second inorganic layer further includes a pixel defining layer on the third inorganic part.

In some embodiments, second mounting grooves corresponding to the first electrodes are provided in the display region, where the second mounting grooves penetrate through the pixel defining layer.

In some embodiments, a first electrode material layer is provided in the non-display region and between the first inorganic layer and the array substrate, where the first electrode material layer and the electrode wire layer are used together to form an electrode area.

according to the second aspect of the embodiments of the present disclosure, a manufacturing method for a display module is provided, and includes:
providing an array substrate;
providing a first inorganic material layer on the array substrate and thinning the first inorganic material layer to form a first inorganic part in a non-display region;
providing a second inorganic layer on the first inorganic layer, where the second inorganic layer includes a second inorganic part on the first inorganic part;
providing a first mounting groove, where the first mounting groove is in the non-display region, surrounds a portion of the display region, and penetrates through the first inorganic part and the second inorganic part, where the first mounting groove is in an open shape, and in a direction from the array substrate towards the second inorganic layer, a groove wall of the first mounting groove is inclined or stepped; and
providing an electrode wire layer in the first mounting groove.

In some embodiments, the groove wall of the first mounting groove is inclined, and a slope angle of the groove wall of the first mounting groove is 20° to 60°.

In some embodiments, before providing the first mounting groove, the method includes:
providing a first etching resist layer in the non-display region on the second inorganic layer; and
forming a first etching groove in the first etching resist layer; and
providing the first mounting groove includes:
etching at the first etching groove to form the first mounting groove.

In some embodiments, the first mounting groove is formed by dry etching.

In some embodiments, the groove wall of the first mounting groove is inclined, and an etching agent for the dry etching includes a mixture of carbon tetrafluoride and oxygen; and
etching at the first etching groove to form the first mounting groove includes:
etching the second inorganic part and the first inorganic part at the first etching groove by carbon tetrafluoride and oxygen with a preset ratio for a first preset duration, to form the first mounting groove.

In some embodiments, the groove wall of the first mounting groove is stepped, and etching at the first etching groove to form the first mounting groove includes:
etching the second inorganic part and the first inorganic part at the first etching groove, to form a first groove part penetrating through the second inorganic part and the first inorganic part;
perform lateral etching on the first etching groove of the first etching resist layer, to form a second etching groove, where an orthographic projection of the first etching groove in a direction from the array substrate towards the second inorganic layer is within an orthographic projection of the second etching groove in the direction from the array substrate towards the second inorganic layer; and
etching the second inorganic part and the first inorganic part at the second etching groove for a second preset duration, to form the first mounting groove.

In some embodiments, before providing the first inorganic layer on the array substrate, the manufacturing method includes:
providing first electrodes on the array substrate, where the first electrodes are in the display region on the array substrate, and arranged in an array; and
providing the first inorganic material layer on the array substrate and thinning the first inorganic material layer to form the first inorganic part in a non-display region includes:
forming a third inorganic part between adjacent two of the first electrodes in the display region, where the first inorganic part and the third inorganic part form the first inorganic layer.

In some embodiments, providing the second inorganic layer on the first inorganic layer includes:
forming a second inorganic layer on the first inorganic part, the third inorganic part, and the first electrodes; and
after providing the first mounting groove and before providing the electrode wire layer in the first mounting groove, the method further includes:
providing a second etching resist layer in the display region on the second inorganic layer;
forming second etching grooves respectively corresponding to the first electrodes in the second etching resist layer; and
etching the second inorganic layer at the second etching grooves to form second mounting grooves respectively corresponding to the first electrodes.

In the above display module and the manufacturing method thereof provided in the present disclosure, the groove wall of the first mounting groove is inclined or the groove wall of the first mounting groove is stepped, such that when the electrode wire layer is arranged in the first mounting groove, the material for forming the electrode wire layer has better continuity on the first mounting groove, which is beneficial to reducing or avoiding the risk of the electrode wire layer breaking on the first mounting groove, thereby, improving the quality of the formed electrode connecting wire (such as cathode area wire).

It is to be understood that the above general descriptions and the below detailed descriptions are merely exemplary and explanatory, and are not intended to limit the present disclosure.

### BRIEF DESCRIPTION OF DRAWINGS

The accompanying drawings herein, which are incorporated in and constitute a part of the present description, illustrate examples consistent with the present disclosure and serve to explain the principles of the present disclosure together with the description.

FIG. 1 is a sectional schematic diagram of a partial structure of a display module in a related technology.

FIG. 2 is a top-view schematic diagram of a display module according to an embodiment of the present disclosure.

FIG. 3 is an enlarged schematic diagram of a partial display region of a display module according to an embodiment of the present disclosure.

FIG. 4 is an enlarged schematic diagram of a partial non-display region of a display module according to an embodiment of the present disclosure.

FIG. 5 is a sectional view of a partial non-display region of a display module according to an embodiment of the present disclosure, where FIG. 5 can be a sectional view at A in FIG. 4.

FIG. 6 is a sectional view of a partial non-display region of another display module according to an embodiment of the present disclosure.

FIG. 7 is a flowchart of a manufacturing method of a display module according to an embodiment of the present disclosure.

FIG. 8 is a diagram for a lateral height coverage process according to an embodiment of the present disclosure.

FIG. 9 is a sectional view of a partial display region after the lateral height coverage process according to an embodiment of the present disclosure.

FIG. 10 is a comparative diagram of a display region and a non-display region under a microlens after the lateral height coverage process according to an embodiment of the present disclosure.

FIG. 11 is a diagram for a relationship between a mixing ratio of an etching agent and a slope of a groove wall of a first mounting groove according to an embodiment of the present disclosure.

FIG. 12 is a diagram for a relationship between an etching time of an etching agent and a slope of a groove wall of a first mounting groove according to an embodiment of the present disclosure.

FIG. 13 is a schematic diagram of a groove wall of the first mounting groove of a display module with a slope angle under a microlens according to an embodiment of the present disclosure.

FIG. 14 is a schematic diagram of a groove wall of the first mounting groove of a display module with another slope angle under a microlens according to an embodiment of the present disclosure.

FIG. 15 is a schematic diagram of another display module under a microlens according to an embodiment of the present disclosure.

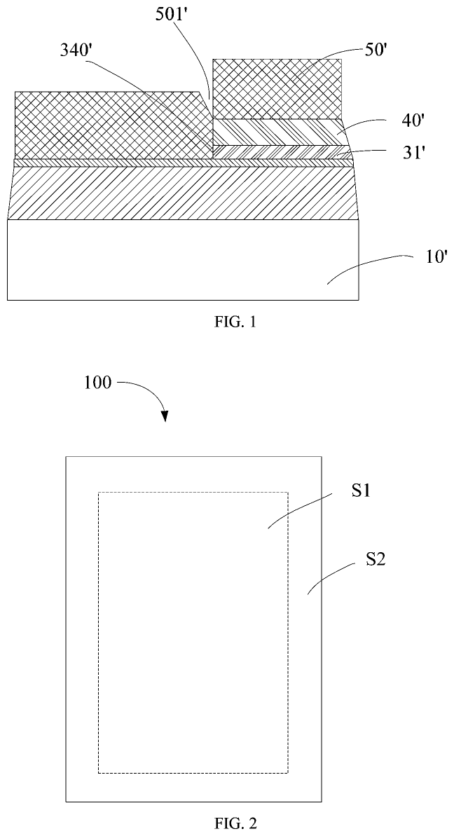

### DETAILED DESCRIPTION

Embodiments will be described in detail herein, examples of which are illustrated in the accompanying drawings. Where the following description refers to the drawings, elements with the same numerals in different drawings refer to the same or similar elements unless otherwise indicated. Implementations described in the following embodiments do not represent all implementations consistent with the present disclosure. On the contrary, they are examples of an apparatus and a method consistent with some aspects of the present disclosure described in detail in the appended claims.

Terms used in the present disclosure is only for the purpose of describing particular embodiments and is not intended to limit the present disclosure. Unless otherwise defined, the technical terms or scientific terms used in the present disclosure shall have the ordinary meanings understood by those skilled in the art to which the present disclosure belongs. The words such as “a” or “an” in the specification and the claims of the present disclosure do not indicate a quantity limitation, but mean that there is at least one. “A plurality of” means two or more. “Include”, “comprise” and similar terms mean that the elements or items listed before “include” or “comprise” include the elements or items listed after “include” or “comprise” and their equivalents, and do not exclude other elements or objects. Words such as “connect” or “couple” are not limited to physical or mechanical connections, and may include electrical connections, whether direct or indirect. Words such as “top” and/or “bottom” are only for illustration purposes and are not limited to a single position or spatial orientation. As used in the present disclosure and the appended claims, the singular forms “a”, “said” and “the” are intended to include the plural forms as well, unless the context clearly indicates otherwise. It should further be understood that the term “and/or” as used herein refers to and includes any and all possible combinations of one or more of the associated listed items.

The present disclosure provides a display module and a manufacturing method thereof. The display module includes a display region and a non-display region located on the periphery of the display region. The display module includes an array substrate, a first inorganic layer, a second inorganic layer, a first mounting groove, and an electrode wire. The first inorganic layer is provided on the array substrate. The first inorganic layer includes a first inorganic part located in the non-display region. The second inorganic layer is provided on a side of the first inorganic layer far from the array substrate. The second inorganic layer includes a second inorganic part located on the first inorganic part. The first mounting groove is located in the non-display region and surrounds a portion of the display region, and the first mounting groove penetrates through the first inorganic part and the second inorganic part. The first mounting groove is in an open shape, and in a direction from the array substrate towards the second inorganic layer, the groove wall of the first mounting groove is inclined, or the groove wall of the first mounting groove is stepped. The electrode wire is at least partially located in the first mounting groove. In the display module, the groove wall of the first mounting groove is inclined or the groove wall of the first mounting groove is stepped, such that when the electrode wire is arranged in the first mounting groove, the material for forming the electrode wire has better continuity on the first mounting groove, which is beneficial to reducing or avoiding the risk of the electrode wire breaking on the first mounting groove.

The display module referred to in the present disclosure can be used to manufacture a display panel, such as a display panel of Micro-OLED display devices, which can be applied to products or components with display functions such as mobile phones, tablet computers, televisions, laptops, etc.

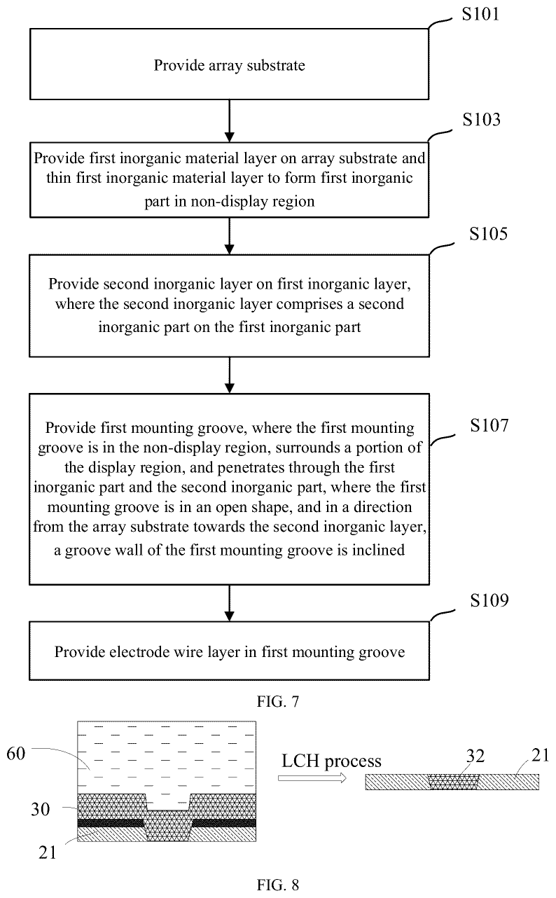

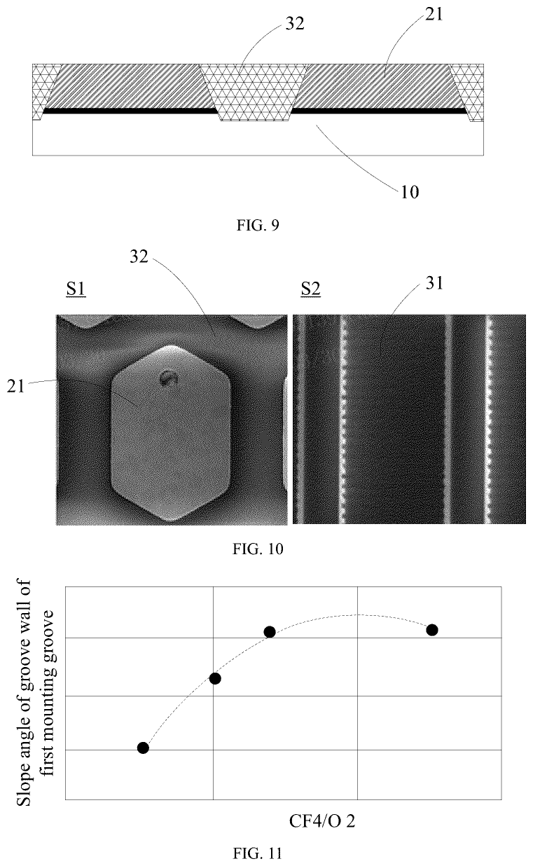

The display module and the manufacturing method thereof provided in the present disclosure will be described in detail below with reference to FIGS. 2 to 15.

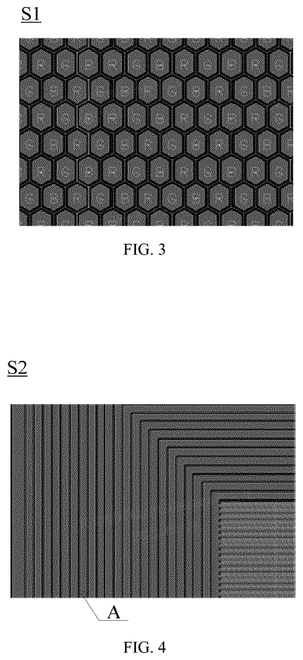

Referring to FIG. 2 and, if necessary, combined with FIGS. 3 to 5, the present disclosure provides a display module 100. The display module 100 has a display region S1 and a non-display region S2 located on the periphery of the display region S1. The display module includes an array substrate 10, a first inorganic layer 30, a second inorganic layer 40, a first mounting groove 340, and an electrode wire layer 50. The first inorganic layer 30 is located on the array substrate 10. The first inorganic layer 30 includes a first inorganic part 31 located in the non-display region S2. The second inorganic layer 40 is located on a side of the first inorganic layer 30 far from the array substrate 10. The second inorganic layer 40 includes a second inorganic part 42 located on the first inorganic part 31. The first mounting groove 340 is located in the non-display region S2 and surrounds a portion of the display region S1, and the first mounting groove 340 penetrates through the first inorganic part 31 and the second inorganic part 42. The first mounting groove 340 is in an open shape, and in a direction from the array substrate 10 towards the second inorganic layer 40, a groove wall 341 of the first mounting groove 340 is inclined or stepped. The electrode wire layer 50 is at least partially located in the first mounting groove 340.

The array substrate referred to here can be understood as a substrate structure with thin film transistors arranged in an array.

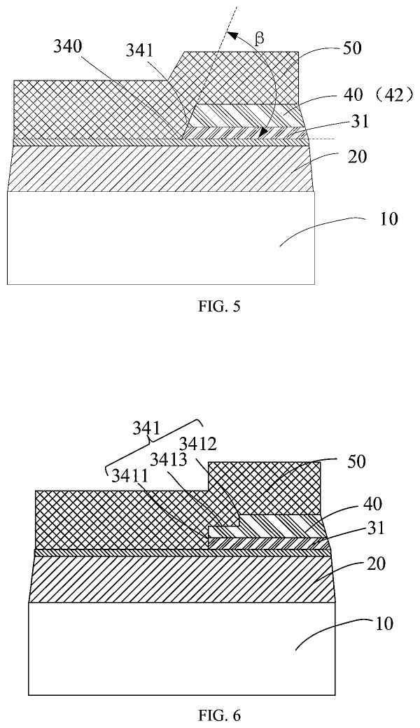

It should be noted that only a portion of the first mounting groove 340 is illustrated in FIG. 5, and in fact, the first mounting groove 340 further has another groove wall opposite to the groove wall 341. The another groove wall and the groove wall 341 can roughly have a symmetrical structure. The higher top surface of the electrode wire layer 50 in FIG. 5 can be used to connect to a negative electrode layer of the display device.

A material of the first inorganic layer can be silicon oxide (SiOx). The first mounting groove 340) can be formed by dry etching.

In some embodiments, inventors have conducted extensive experiments and found that the inclined groove wall 341 of the first mounting groove 340 has a slope angle β, and when the slope angle β of the groove wall 341 is 20° to 60°, when the electrode wire layer 50 is subsequently provided, the material continuity of the electrode wire layer 50 can be better ensured. In some embodiments, the slope angle β of the groove wall 341 is 20° to 50°.

In some embodiments, the display module includes a plurality of first electrodes 21. The plurality of first electrodes 21 are arranged in an array on the array substrate 10 and in the display region S1. The first inorganic layer 30 further includes a third inorganic part 32 located between two adjacent first electrodes 21 in the display region S1. The second inorganic layer 40 further includes a pixel defining layer located on the third inorganic part 32.

The first electrode 21 referred to here can be understood as the anode in the light-emitting layer.

The surface of the third inorganic part 32 far from the array substrate 10 is flush or roughly flush with the surface of the first electrode 21 far from the array substrate 10.

The third inorganic component 32 can be formed through the LHC process. Correspondingly, the first inorganic part 31 mentioned above can be understood as the portion of the inorganic material layer that has not been etched off during the LHC process.

In some embodiments, the display region S1 is provided with a plurality of second mounting grooves corresponding to the plurality of first electrodes 21, and the second mounting groove penetrates through the pixel defining layer.

The second mounting groove can be used for subsequent mounting of an organic light-emitting material layer and a corresponding second electrode. The second mounting groove can be formed after the formation of the first mounting groove. The second electrode mentioned here can be understood as the negative electrode in the light-emitting layer.

The second mounting groove can be formed by dry etching. The etching agent can be carbon tetrafluoride or a mixture of carbon tetrafluoride and a small amount of oxygen. The groove wall of the second mounting groove is nearly vertical. The slope angle of the groove wall of the second mounting groove can be approximately 80° to 90°.

In some embodiments, the non-display region S2 is provided with a first electrode material layer located between the first inorganic layer 30 and the array substrate 10. The first electrode material layer and the electrode wire layer 50 are together used to form an electrode area. The electrode area referred to here can be understood as the cathode area, which is an electrical connection wire structure used to connect the negative electrode (the second electrode).

Referring to FIG. 6. the present disclosure further provides another display module. FIG. 6 is a sectional view of a partial non-display region of another display module. The structure of this display module is similar to the structure of the above display module 100. Anything in common or similar can be referred to in the relevant description above, which will not be repeated here. Here, mainly the differences are described. Unlike the display module 100 mentioned above, in this embodiment, the groove wall 341 of the first mounting groove 340 is stepped. For example, as shown in FIG. 6, the groove wall 341 of the first mounting groove 340 includes a first groove wall 3411 close to the array substrate 10, a second groove wall 3412 far from the array substrate 10, and a third groove wall 3413 connected between the first groove wall 3411 and the second groove wall 3412, to form a step.

The first groove wall 3411 and the second groove wall 3412 here extend roughly along the direction from the array substrate 10 towards the second inorganic layer 40. The step formed by the third groove wall 3413 roughly extend horizontally, for example, in the direction perpendicular to the first groove wall 3411.

It should be noted that the stepped shape here can include one or more steps. The first groove wall and the second groove wall can be slightly inclined, and the third groove wall can also be slightly inclined, which is not limited in the present disclosure, and can be set according to specific circumstances.

Referring to FIG. 7, the present disclosure provides a manufacturing method for a display module. The manufacturing method can be used to manufacture the above display module 100. The manufacturing method may include follow steps S101 to S109.

In step S101, an array substrate 10 is provided.

In step S103, a first inorganic material layer is provided on the array substrate 10, and the first inorganic material layer is thinned to form a first inorganic part 31 located in the non-display region S2.

In step S105, a second inorganic layer 40 is provided on the first inorganic layer 30. The second inorganic layer 40 includes a second inorganic part 42 located on the first inorganic part 31.

In step S107, a first mounting groove 340 is provided in a non-display region S2, where the first mounting groove 340 surrounds a portion of the display region S1, and penetrates through the first inorganic part 31 and the second inorganic part 42, where the first mounting groove 340 is in an open shape, and the groove wall 341 of the first mounting groove 340 is inclined in the direction from the array substrate 10 towards the second inorganic layer 40.

In step S109, an electrode wire layer 50 is provided in the first mounting groove 340.

In some embodiments, inventors have conducted extensive experiments and found that the inclined groove wall 341 of the first mounting groove 340 has a slope angle β, and when the slope angle β of the groove wall 341 is 20° to 60°, when the electrode wire layer 50 is subsequently provided, the material continuity of the electrode wire layer 50 can be better ensured. In some embodiments, the slope angle β of the groove wall 341 is 20° to 50°.

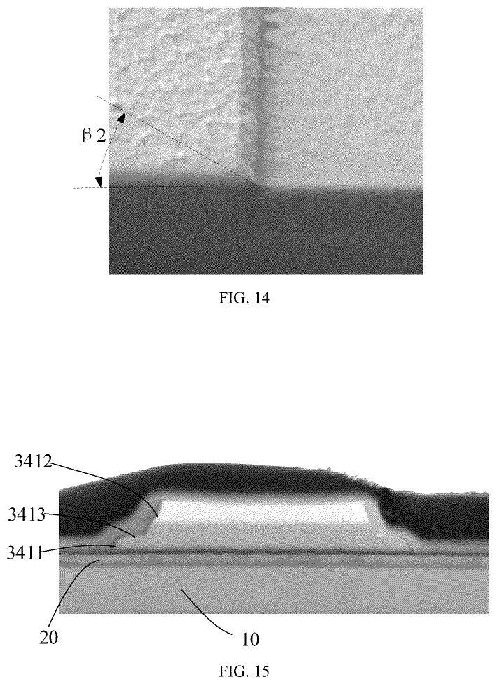

For example, as shown in FIGS. 13 and 14, in the structure shown in FIG. 13, the slope angle β1 of the groove wall 341 is approximately 20°. In the structure shown in FIG. 14, the slope angle β2 of the groove wall 341 is approximately 45°.

In some embodiments, before step S107, the method includes:
providing a first etching resist layer in the non-display region S2 on the second inorganic layer 40; and
forming a first etching groove in the first etching resist layer.

Correspondingly, step S107 can be achieved through the following step S1071.

In step S1071, the first mounting groove 340 is formed by etching at the first etching groove.

In some embodiments, the first mounting groove 340 is formed by dry etching.

In some embodiments, an etching agent for the dry etching includes a mixture of carbon tetrafluoride and oxygen. During etching, inert gases such as helium can further be added to the mixture to ensure the pressure of the etching environment.

Step S1071 can be achieved through the following steps:
etching the second inorganic part 42 and the first inorganic part 31 at the first etching groove by carbon tetrafluoride and oxygen with a preset ratio for a first preset duration, to form the first mounting groove 340.

It should be noted that the slope angle of the groove wall 341 of the first mounting groove 340 is related to the ratio of carbon tetrafluoride and oxygen and the etching duration. When forming the first mounting groove 340, the preset ratio of carbon tetrafluoride and oxygen and the etching duration can be determined according to the specific situation.

As shown in FIG. 11, the inventors found through research that in some embodiments, the proportion of carbon tetrafluoride in the etching agent is positively correlated with the slope angle of the groove wall 341. The larger the proportion of carbon tetrafluoride in the etching agent, the greater the slope angle of the groove wall 341.

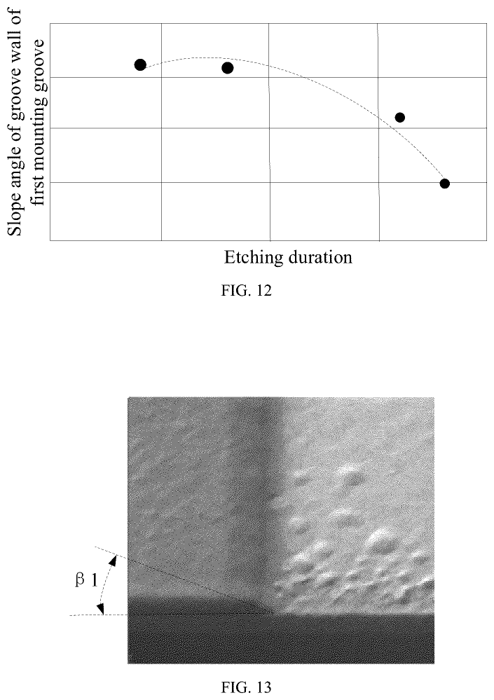

As shown in FIG. 12, the inventors found through research that in some embodiments, for the same etching agent, the etching duration is negatively correlated with the slope angle of the groove wall 341. The longer the etching duration, the smaller the slope angle of groove wall 341.

It should also be noted that the formation of the first mounting groove 340 can use an End Point Detection (EPD) to determine and control the end action of etching by obtaining spectral signals of the structure. Mainly by comparing the spectra of the first inorganic part 31 and the second inorganic part 42 stacked close to the bottom of the first mounting groove 340, it can be determined whether the first inorganic part 31 at the bottom of the first mounting groove 340 is completely etched.

In some embodiments, before step S103, the method includes the following steps:
providing first electrodes 21 on the array substrate 10, where the first electrodes 21 are in the display region S1 on the array substrate 10, and arranged in an array.

Correspondingly, in step S103, when a first inorganic material layer is provided on the array substrate 10 and the first inorganic material layer is thinned to form the first inorganic part 31 in the non-display region S2, a third inorganic part 32 can be simultaneously formed between adjacent first electrodes 21 in the display region S1. The first inorganic part 31 and the third inorganic part 32 form the first inorganic layer 30.

In some embodiments, providing the second inorganic layer 40 on the first inorganic layer 30 includes:
forming a second inorganic layer 40 on the first inorganic part 31, the third inorganic part 32, and the first electrodes 21. The second inorganic layer 40 covers both the display region and the non-display region.

Correspondingly, after step S107 and before step S109, the method further includes:
providing a second etching resist layer in the display region S1 on the second inorganic layer 40;
forming second etching grooves respectively corresponding to the first electrodes 21 in the second etching resist layer; and
etching the second inorganic layer 40 at the second etching grooves to form second mounting grooves respectively corresponding to the first electrodes 21.

The second mounting groove can also be formed by dry etching. The etching agent can be carbon tetrafluoride or a mixture of carbon tetrafluoride and a small amount of oxygen. The wall of the second mounting groove is nearly vertical. The slope angle of the groove wall of the second mounting groove can be approximately 80° to 90°.

The present disclosure further provides another manufacturing method for a display module, which can be used to manufacture the display module as shown in FIG. 6. This manufacturing method is roughly related to the above manufacturing method shown in FIG. 7. Anything in common or similar can be referred to in the relevant description above. Here, mainly the differences are described. Different from the manufacturing method of the display module mentioned above, here, the first mounting groove 340 provided in step S107 has a stepped groove wall 341.

Correspondingly, the method in step S107 is also different. Here, step S1071 can be achieved through the following steps S171 to S175.

In step S171, the second inorganic part 42 and the first inorganic part 31 at the first etching groove are etched, to form a first groove part penetrating through the second inorganic part 42 and the first inorganic part 31.

It should also be noted that the formation of the first groove part can use an End Point Detection (EPD) to determine and control the end action of etching by obtaining spectral signals of the structure. Mainly by comparing the spectra of the first inorganic part 31 and the second inorganic part 42 stacked close to the bottom of the first groove part, it can be determined whether the first inorganic part 31 at the bottom of the first mounting groove 340 is completely etched.

In step S173, lateral etching is performed on the first etching groove of the first etching resist layer, to form a second etching groove, where an orthographic projection of the first etching groove in a direction from the array substrate 10 towards the second inorganic layer 40 is within an orthographic projection of the second etching groove in the direction from the array substrate 10 towards the second inorganic layer 40.

Here, oxygen can be used to perform lateral etching on the first etching groove of the first etching resist layer.

It should be noted that the thickness of the first etching resist layer can be greater than the thickness of the second etching resist layer, to ensure that when oxygen is used to perform lateral etching on the first etching groove of the first etching resist layer, the first etching resist layer still has a certain thickness after a part of the first etching resist layer with a thickness far from the array substrate 10 is etched off.

In step S175, the second inorganic part 42 and the first inorganic part 31 at the second etching groove are etched for a second preset duration, to form the first mounting groove 340.

Here, different second preset durations can be determined to form different first mounting grooves 340. The longer the second preset duration, the closer the formed third groove wall 3413 of the first mounting groove 340 to the substrate. On the contrary, the shorter the second preset duration, the farther the formed third groove wall 3413 of the first mounting groove 340 from the substrate. In the present disclosure, the terms “first” and “second” are only for descriptive purposes, and cannot be understood as indicating or implying relative importance. The term “plurality of” and “several” means two or more, unless otherwise clearly defined.

After considering and practicing the disclosure of the specification, other embodiments of the present disclosure will be readily apparent to those skilled in the art. The present disclosure is intended to cover any modification, use or adaptation of the present disclosure. These modifications, uses or adaptations follow the general principles of the present disclosure and include common knowledge and conventional technical means in the technical field that are not disclosed in the present disclosure. The specification and embodiments herein are intended to be illustrative only and the real scope and spirit of the present disclosure are indicated by the claims of the present disclosure.

It is to be understood that the present disclosure is not limited to the precise structures described above and shown in the accompanying drawings and may be modified or changed without departing from the scope of the present disclosure. The scope of protection of the present disclosure is limited only by the appended claims.

1. A display module comprising a display region and a non-display region at a periphery of the display region, wherein the display module comprises:
an array substrate;
a first inorganic layer on the array substrate, wherein the first inorganic layer comprises a first inorganic part in the non-display region;
a second inorganic layer on a side of the first inorganic layer far from the array substrate, wherein the second inorganic layer comprises a second inorganic part on the first inorganic part;
a first mounting groove in the non-display region, surrounding a portion of the display region, and penetrating through the first inorganic part and the second inorganic part, wherein the first mounting groove is in an open shape, and in a direction from the array substrate towards the second inorganic layer, a groove wall of the first mounting groove is inclined or stepped; and
an electrode wire layer at least partially in the first mounting groove.

2. The display module according to claim 1, wherein the groove wall of the first mounting groove is inclined, and a slope angle of the groove wall of the first mounting groove is 20° to 60°.

3. The display module according to claim 1, wherein the groove wall of the first mounting groove is stepped, and the groove wall of the first mounting groove comprises a first groove wall close to the array substrate, a second groove wall far from the array substrate, and a third groove wall connected between the first groove wall and the second groove wall, wherein a step is formed by the third groove wall.

4. The display module according to claim 1, further comprising:
first electrodes in the display region on the array substrate and arranged in an array, wherein the first inorganic layer further comprises a third inorganic part between adjacent two of the first electrodes in the display region, and the second inorganic layer further comprises a pixel defining layer on the third inorganic part.

5. The display module according to claim 4, wherein second mounting grooves respectively corresponding to the first electrodes are provided in the display region, wherein the second mounting grooves penetrate through the pixel defining layer.

6. The display module according to claim 4, wherein a first electrode material layer is provided in the non-display region and between the first inorganic layer and the array substrate, wherein the first electrode material layer and the electrode wire layer are used together to form an electrode area.

7. A manufacturing method for a display module, comprising:
providing an array substrate;
providing a first inorganic material layer on the array substrate and thinning the first inorganic material layer to form a first inorganic part in a non-display region;
providing a second inorganic layer on a first inorganic layer, wherein the second inorganic layer comprises a second inorganic part on the first inorganic part;
providing a first mounting groove, wherein the first mounting groove is in the non-display region, surrounds a portion of the display region, and penetrates through the first inorganic part and the second inorganic part, wherein the first mounting groove is in an open shape, and in a direction from the array substrate towards the second inorganic layer, a groove wall of the first mounting groove is inclined or stepped; and
providing an electrode wire layer in the first mounting groove.

8. The manufacturing method according to claim 7, wherein the groove wall of the first mounting groove is inclined, and a slope angle of the groove wall of the first mounting groove is 20° to 60°.

9. The manufacturing method according to claim 7, wherein the manufacturing method comprises:
providing a first etching resist layer in the non-display region on the second inorganic layer; and
forming a first etching groove in the first etching resist layer; and
providing the first mounting groove comprises:
etching at the first etching groove to form the first mounting groove.

10. The manufacturing method according to claim 9, wherein the first mounting groove is formed by dry etching.

11. The manufacturing method according to claim 10, wherein the groove wall of the first mounting groove is inclined, an etching agent for the dry etching comprises a mixture of carbon tetrafluoride and oxygen, and etching at the first etching groove to form the first mounting groove comprises:
etching the second inorganic part and the first inorganic part at the first etching groove by carbon tetrafluoride and oxygen with a preset ratio for a first preset duration, to form the first mounting groove.

12. The manufacturing method according to claim 10, wherein the groove wall of the first mounting groove is stepped, and etching at the first etching groove to form the first mounting groove comprises:
etching the second inorganic part and the first inorganic part at the first etching groove, to form a first groove part penetrating through the second inorganic part and the first inorganic part;
performing lateral etching on the first etching groove of the first etching resist layer, to form a second etching groove, wherein an orthographic projection of the first etching groove in a direction from the array substrate towards the second inorganic layer is within an orthographic projection of the second etching groove in the direction from the array substrate towards the second inorganic layer; and
etching the second inorganic part and the first inorganic part at the second etching groove for a second preset duration, to form the first mounting groove.

13. The manufacturing method according to claim 7, wherein the manufacturing method comprises:
providing first electrodes on the array substrate, wherein the first electrodes are in the display region on the array substrate, and arranged in an array; and
forming a third inorganic part between adjacent two of the first electrodes in the display region, wherein the first inorganic part and the third inorganic part form the first inorganic layer.

14. The manufacturing method according to claim 13, wherein providing the second inorganic layer on the first inorganic layer comprises:
forming the second inorganic layer on the first inorganic part, the third inorganic part, and the first electrodes.

15. The manufacturing method according to claim 13, further comprising:
providing a second etching resist layer in the display region on the second inorganic layer;
forming second etching grooves respectively corresponding to the first electrodes in the second etching resist layer; and
etching the second inorganic layer at the second etching grooves to form second mounting grooves respectively corresponding to the first electrodes.

16. The manufacturing method according to claim 15, wherein the second mounting groove is formed by dry etching.

17. The manufacturing method according to claim 15, wherein a groove wall of the second mounting groove is nearly vertical, and a slope angle of the groove wall of the second mounting groove is approximately 80° to 90°.

18. The manufacturing method according to claim 16, wherein an etching agent for the dry etching includes a mixture of carbon tetrafluoride and oxygen.

19. The manufacturing method according to claim 11, wherein a proportion of carbon tetrafluoride in the etching agent is positively correlated with a slope angle of the groove wall, and the larger the proportion of carbon tetrafluoride in the etching agent, the greater the slope angle of the groove wall.

20. The manufacturing method according to claim 11, wherein for the same etching agent, etching duration is negatively correlated with a slope angle of the groove wall, and the longer the etching duration, the smaller the slope angle of groove wall.
